(19) United States
(12) Patent Application Publication
(10) Pub. No.: US 2009/0289631 A1
(43) Pub. Date: Nov. 26, 2009

(54) MAGNETIC RESONANCE IMAGING WITH MULTIPLE CONTRAST

(75) Inventors: Johan Samuel Van Den Brink, Eindhoven (NL); Franciscus Johannes Maria Benschop, Eindhoven (NL)

Correspondence Address: PHILIPS INTELLECTUAL PROPERTY & STANDARDS, P. O. Box 3001, BRIARCLIFF MANOR, NY, 10510, US

(73) Assignee: KONINKLIJKE PHILIPS ELECTRONICS N.V., Eindhoven (NL)

(21) Appl. No.: 11/721,178

(22) PCT Filed: Dec. 13, 2005
(86) PCT No.: PCT/IB05/54218

§ 371 Date: Jun. 8, 2007

(30) Foreign Application Priority Data
Dec. 21, 2004 (EP) 04106761.2

(51) Int. Cl. G01R 33/48

(52) U.S. Cl. 324/309

(57) ABSTRACT

A magnetic resonance imaging system comprises an RF-excitation module to generate one of several RF-excitations and a gradient module to generate one of several magnetic gradient pulses, a control unit controls the RF-excitation module and the gradient module and performs an acquisition sequence containing a succession of RF-excitations and gradient pulses. The acquisition sequence comprising several acquisition segments in which magnetic resonance signals are generated, in respective segments different contrast types occur. Individual acquisition segments have one or several repetitive acquisition units, magnetic resonance signals in an individual acquisition unit pertaining to the same contrast type. This approach of acquisition of different contrast type per group of acquisition segments allows optimisation of the acquisition of each of the contrast type independently of the contrast type of other groups of acquisition segments.

The invention pertains to a magnetic resonance imaging system which has the capability to generate magnetic resonance signals of several types of contrast. Such a magnetic resonance imaging system is known from the U.S.-patent U.S. Pat. No. 6,075,362.

The known magnetic resonance imaging system operates to induce a train of magnetic resonance echoes upon an excitation. The excitation concerns the excitation of magnetic resonance in selected dipoles in an imaging region. That is, this excitation functions as an RF-excitation. The echoes are phase and frequency encoded to generate data lines of a first and second image at different echo times. The echoes are interleaved for the respective images. Accordingly, due to the differences in echo times, the contrast in the respective images is of different types. In fact, the known magnetic resonance imaging system generates in an interleaved way magnetic resonance signals that represent typically T₁-contrast and T₂-contrast, respectively.

An object of the invention is to provide a magnetic resonance imaging system that has improved flexibility to generate magnetic resonance signals that represent various types of contrast.

This object is achieved by the magnetic resonance imaging system of the invention, which comprises

an RF-excitation module to generate one of several RF-excitations

a gradient module to generate one of several magnetic gradient pulses

a control unit to control the RF-excitation module and the gradient module and the control unit being arranged to

perform an acquisition sequence containing a succession of RF-excitations and gradient pulses

the acquisition sequence comprising several acquisition segments in which magnetic resonance signals are generated, in respective segments the magnetic resonance signals pertaining to different contrast types

individual acquisition segments have one or several repetitive acquisition units, magnetic resonance signals in an individual acquisition unit pertaining to the same contrast type.

The invention is based on the insight that the acquisition of magnetic resonance signals is divided into several acquisition segments. Individual acquisition segments involve the acquisition of magnetic resonance signals of a particular type of contrast. Thus in general, there are acquired magnetic resonance signals of a particular type of contrast in one or several acquisition segments for that contrast type, while the magnetic resonance signals of a different type of contrast are acquired in one or several other acquisition segments. Each of the acquisition segments involves a magnetic resonance acquisition sequence that for example contains RF-pulses and temporary magnetic gradient fields during which magnetic resonance signals are generated and acquired. The temporary magnetic gradient fields are superimposed on the main magnetic field of the magnetic resonance imaging system and serve to generate a spatial encoding of the magnetic resonance signals. These temporary magnetic gradient fields are also indicated as gradient pulses. Often there are employed read gradient pulses that are present during actual acquisition of magnetic resonance signals and there are phase encoding gradient pulses that are present separately from acquisition of magnetic resonance signals. These magnetic resonance signals acquisition sequences are built up from repeating acquisition units. According to the invention, in individual acquisition units magnetic resonance signals are acquired of the same contrast type. During an individual acquisition segment the acquisition unit may be repeated several times, for example to generate multiple echoes and/or to establish a steady-state acquisition type. Among the acquisition segments there are two or more groups to be distinguished. Within acquisition segments of one group a particular type of contrast is carried by the magnetic resonance signals acquired in that segment. However, in different groups of acquisition segments different types of contrast are involved. The acquisition segments of several groups may be alternated in various degrees, that is the may be alternated among acquisition segments from different groups from one acquisition to the next, or a number of acquisition segments from one group may be followed by a number (same or different) of acquisition segments from another group. This approach of acquisition of different contrast type per group of acquisition segments allows optimisation of the acquisition of each of the contrast type independently of the contrast type of other groups of acquisition segments. In the sequence of acquisition segments successive acquisition segments can be subject to different types of constraints. For example one acquisition segment may be subject to a constraint of not exceeding maximum SAR (specific absorption ratio), while the next acquisition segment is subject to a constraint due to the performance limit of the gradient module. Further, within an acquisition segment the repetitions of an acquisition unit may be set independently of the way other acquisition segments are built up. In this way, further optimisation of each acquisition segment independently of the other acquisition segment is achieved. Also, there is no need to employ a profile sharing between acquisition segments. That is the acquisition segments can be carried out without k-space profiles of either acquisition segments that are common to these acquisition segments. For example the echo train lengths (i.e. the number of magnetic resonance signals in the form of echoes per RF-excitation pulse) can be varied independently for respective contrast types.

These and other aspects of the invention will be further elaborated with reference to the embodiments defined in the dependent Claims.

According to one aspect of the invention the duration of the acquisition segments is set on the basis of their contents. The content of the acquisition segments is derived from the content in terms of e.g. RF pulses (excitation pulses, refocusing pulses, inversion pulses etc.) and temporary gradient (gradient pulses such as read gradients, phase encoding gradients, diffusion or flow sensitising gradients etc.) that occur in the acquisition units and the number of acquisition units employed in the acquisition segment. The number of acquisition unit in the respective acquisition segments may be set on the basis of the constraint at issue that is to be met. According to particular examples, the duration of a particular acquisition segment may be set on the basis of its contents in such a way that the relevant SAR limit is not exceeded or in such a way that the maximum performance of the gradient module is not exceeded. In practice, the maximum performance of the gradient module is expressed in terms of a maximum average over a preset period of time of the performance (e.g. signal power) of the gradient module. In particular, the duration of the acquisition sequences is set on the basis of a duty-cycle limitation that is derived from the contents of the acquisition segments. The setting of the duration of the acquisition segments may be done on the basis of user input. Such user input is input to the control unit via a user input. Setting the duration of the acquisition segments on the basis of user input achieves that it is easy for the operator to set the acquisition segments according to the personal preference of the operator. In an alternative embodiment the control unit is arranged to compute the duration of the acquisition segments on the basis of their content. Then less user intervention is required to achieve the duration of the acquisition segments. It is noted that the duration of the acquisition segments concerns the number of repetitions of their acquisition units. Accordingly, the duration of the acquisition segments in units of time is given by the duration of the acquisition unit at issue times the number of its repetitions. Often, the segmentation of the acquisition of each type of contrast can be done according to natural segmentation boundaries of the acquisition for the type of contrast at issue. These natural segmentation boundaries separate portions of the acquisition sequence of which their content has a high number of elements in common.

According to another aspect of the invention the duration of the acquisition segments is set on the basis of the constraint while taking a pre-selected safety margin into account. The pre-selected safety margin is for example a selected fraction of or a nominal period from the duration of the acquisition segment at which the constraint is met. The selected fraction or nominal period can be selected by the user, optionally in dependence of the type of contrast at issue. Alternatively, the selected fraction or nominal period may be automatically selected by the control unit. This is achieved by software that computes the safety margin on the basis of the types of contrast that occur in the acquisition sequence that is carried out. When such a safety margin is employed the risk that one or several of the constraints are violated is reduced.

The invention achieves that magnetic resonance acquisition sequences to remain within particular constraints such as the SAR limit and the maximum gradient performance, while time periods where the magnetic resonance system is idle as to the acquisition of signals is avoided or substantially reduced. Other examples of constraints that are an issue in magnetic resonance imaging are B₀-drift, RF duty cycle, acoustic noise level, the duration of breath hold the patient is capable of. The present invention allows to overcome to a large degree to meet these constraints without the need to turn to substantially longer acquisition times.

For example, one diffusion group of acquisition segments may concern diffusion weighted contrast, while another TSE-group of acquisition segments concerns a TSE (turbo-spin echo) acquisition. The acquisition segments of the diffusion group have a duration set on the basis of the maximum gradient performance in view of the diffusion gradients required for the diffusion weighting. The acquisition segments of the TSE-group are set according the SAR limit that is of relevance in view of the relatively large number of RF refocusing pulses. Acquisition segments of the diffusion group can be carried out while acquisition segments of the TSE group are obstructed by the SAR limit and the other way round, the acquisition of the TSE-group can be carried out while the acquisition segments of the diffusion group are obstructed by the maximum gradient performance. Hence, the SAR limit and the maximum gradient performance have less negative effect on the efficiency of the overall data acquisition.

According to a further aspect of the invention the duration of the acquisition segments can be set manually by the user. To this end the control unit is provided with a user input to receive the set duration of the acquisition segments. Accordingly, the user can personalise the durations of the acquisition segments and take into account particular circumstances of the MR-examination in point.

According to another aspect of the invention the control unit computes the duration of the acquisition segments. This computation is made on the basis of the content of the acquisition segments, notably the RF-pulses, temporary magnetic gradient fields (gradient pulses) and their waveforms in the acquisition units and the number of repetitions of the various acquisition units. The computation for example takes into account various restrictions such as SAR-limits and the maximum gradient performance to produce durations of acquisition segments that comply with the restrictions and also minimise the time the magnetic resonance imaging system is idle, notably in that there is no acquisition of magnetic resonance signals taking place. The duration of the acquisition segments, notably in term of the number of repetitions of the acquisition units in the acquisition segment is set at, just below or at a preset percentage or a preset offset below the maximum duration. The term maximum duration represents the duration of the acquisition segment at which the relevant constraint is exceeded if the duration is made longer.

According to a further aspect of the invention the control unit is also arranged to control the receiver module and the reconstruction module of the magnetic resonance imaging system. The receiver module is controlled to collect magnetic resonance signals of acquisition segments that are needed to reconstruct a magnetic resonance image of a particular contrast. Notably, the control unit controls the receiver unit to assemble collected magnetic resonance signals of acquisition segments of respective contrast types in different signal packages. In this way cross talk among the magnetic resonance signals is avoided. Also the reconstruction module is controlled to perform the reconstruction from the magnetic resonance signals of the acquisition segments of that type of contrast. This may be done on the assembled packages for each of the types of contrast.

The invention also relates to a magnetic resonance imaging method as defined in Claim 7. This magnetic resonance imaging method of the invention achieves optimisation of the acquisition of each of the contrast type independently of the contrast type of other groups of acquisition segments. The invention further relates to a computer programme as defined in Claim 8. The computer programme of the invention can be provided on a data carrier such as a CD-rom disk, or the computer programme of the invention can be downloaded from a data network such as the world-wide web. When installed in the computer included in a magnetic resonance imaging system the magnetic resonance imaging system is enabled to operate according to the invention and achieves optimisation of the acquisition of each of the contrast type independently of the contrast type of other groups of acquisition segments.

These and other aspects of the invention will be elucidated with reference to the embodiments described hereinafter and with reference to the accompanying drawing wherein

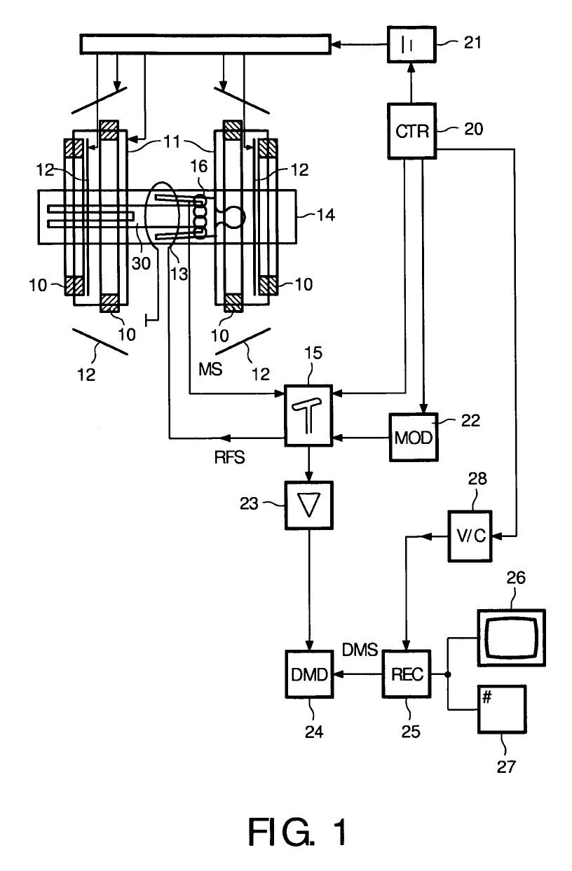

FIG. 1 shows a diagrammatic representation of a magnetic resonance imaging system in which the invention is employed.

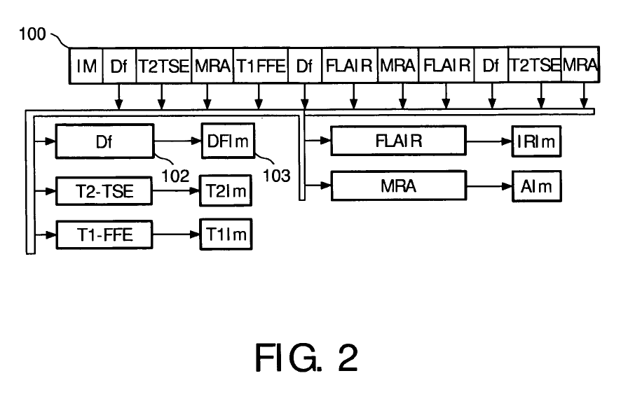

FIG. 2 shows a diagrammatic representation of a mode of operation of the magnetic resonance imaging system of the invention.

The FIG. 1 shows diagrammatically a magnetic resonance imaging system in which the invention is used. The magnetic resonance imaging system includes a set of main coils 10 whereby the steady, uniform magnetic field is generated. The main coils are constructed, for example in such a manner that they enclose a tunnel-shaped examination space. The patient to be examined is placed on a patient carrier which is slid into this tunnel-shaped examination space. The magnetic resonance imaging system also includes a number of gradient coils 11, 12 whereby magnetic fields exhibiting spatial variations, notably in the form of temporary gradients in individual directions, are generated so as to be superposed on the uniform magnetic field. The gradient coils 11, 12 are connected to a controllable power supply unit 21. the gradient coils 11, 12 are energised by application of an electric current by means of the power supply unit 21; to this end the power supply unit is fitted with electronic gradient amplification circuit that applies the electric current to the gradient coils so as to generate gradient pulses (also termed ‘gradient waveforms’) of appropriate temporal shape The strength, direction and duration of the gradients are controlled by control of the power supply unit. The magnetic resonance imaging system also includes transmission and receiving coils 13, 16 for generating the RF excitation pulses and for picking up the magnetic resonance signals, respectively. The transmission coil 13 is preferably constructed as a body coil 13 whereby (a part of) the object to be examined can be enclosed. The body coil is usually arranged in the magnetic resonance imaging system in such a manner that the patient 30 to be examined is enclosed by the body coil 13 when he or she is arranged in the magnetic resonance imaging system. The body coil 13 acts as a transmission antenna for the transmission of the RF excitation pulses and RF refocusing pulses. Preferably, the body coil 13 involves a spatially uniform intensity distribution of the transmitted RF pulses (RFS). The same coil or antenna is usually used alternately as the transmission coil and the receiving coil. Furthermore, the transmission and receiving coil is usually shaped as a coil, but other geometries where the transmission and receiving coil acts as a transmission and receiving antenna for RF electromagnetic signals are also feasible. The transmission and receiving coil 13 is connected to an electronic transmission and receiving circuit 15.

It is to be noted that it is alternatively possible to use separate receiving and/or transmission coils 16. For example, surface coils 16 can be used as receiving and/or transmission coils. Such surface coils have a high sensitivity in a comparatively small volume. The receiving coils, such as the surface coils, are connected to a demodulator 24 and the received magnetic resonance signals (MS) are demodulated by means of the demodulator 24. The demodulated magnetic resonance signals (DMS) are applied to a reconstruction unit. The receiving coil is connected to a preamplifier 23. The preamplifier 23 amplifies the RF resonance signal (MS) received by the receiving coil 16 and the amplified RF resonance signal is applied to a demodulator 24. The demodulator 24 demodulates the amplified RF resonance signal. The demodulated resonance signal contains the actual information concerning the local spin densities in the part of the object to be imaged. Furthermore, the transmission and receiving circuit 15 is connected to a modulator 22. The modulator 22 and the transmission and receiving circuit 15 activate the transmission coil 13 so as to transmit the RF excitation and refocusing pulses. The reconstruction unit derives one or more image signals from the demodulated magnetic resonance signals (DMS), which image signals represent the image information of the imaged part of the object to be examined. The reconstruction unit 25 in practice is constructed preferably as a digital image processing unit 25 which is programmed so as to derive from the demodulated magnetic resonance signals the image signals which represent the image information of the part of the object to be imaged. The signal on the output of the reconstruction monitor 26, so that the monitor can display the magnetic resonance image. It is alternatively possible to store the signal from the reconstruction unit 25 in a buffer unit 27 while awaiting further processing.

The magnetic resonance imaging system according to the invention is also provided with a control unit 20, for example in the form of a computer which includes a (micro)processor. The control unit 20 controls the execution of the RF excitations and the application of the temporary gradient fields. To this end, the computer program according to the invention is loaded, for example, into the control unit 20 and the reconstruction unit 25.

FIG. 2 shows a diagrammatic representation of a mode of operation of the magnetic resonance imaging system of the invention. In the example of FIG. 2 there are several groups of acquisition segments, such as a diffusion group, (Df), a T2-TSE group (T2TSE), a magnetic resonance angiography group (MRA), a T1-FFE group (T1FFE) and a FLAIR group (FLAIR). The acquisition segments are shown in a time succession 100, and the relative durations of the acquisition segments 101 are qualitatively shown. The magnetic resonance signals acquired in each of the respective group are collected in the corresponding magnetic resonance signal collections 102, such as a Df-collection, a T2TSE collection, a T1FFE collection, a FLAIR collection and an MRA collection. The reconstruction unit . . . reconstructs respective magnetic resonance images 103 from these collections 102. That is, from the Df-collection a diffusion weighted magnetic resonance image (DfIm) is reconstructed, from the T2TSE-collection a T2-weighted magnetic resonance image (T2Im) is reconstructed, from the T1FFE-collection a T1-weighted magnetic resonance image (T1Im) is reconstructed, from the FLAIR-collection a inversion recovery magnetic resonance image (IRIm) is reconstructed and from the MRA-collection a magnetic resonance angiographic image (AIm) is reconstructed.

In the simplest case, the diffusion scan can be segmented in parts of (say) 1.5 minute duration. This is very easy to be done, since the scan by nature consists of segment separated at natural boundaries: (‘diffusion directions’, typically 6-30; ‘diffusion weightings’ typically 24; averages, typically 2-6). Each individual segment can be separated in time without much penalty. It is advantageous, however, from a magnetization steady state perspective, to fill the full time allowed by the typical duty cycle time constant involved. In this simple case, the examination sequence would change from {T1-FFE; T2-TSE; FLAIR; diffusion-EPI; MRA} into {diffusion-segment1; T1-FIE; diffusion-segment2; T2-TSE; diffusion-segment3; FLAIR; diffusion-segment4; MRA}. The user is not involved in this reshuffling, it is controlled by an ‘optimise’ function in the ExamCards software. In more advanced cases, one would split the T2-TSE and the MRA sequences, too. This is often trivial as well, e.g. by splitting at ‘averages’ segments (typically shorter than the SAR limiting time constant), or for MRA on ‘chunks’ segments. The latter is to be understood as follows: for MRA, multiple segments of a full 3 D volume are acquired in parts (‘chunks’) to improve the inflow contrast. Each ‘chunk’ can easily be treated as a segment that can be interleaved with other sequence segments. Some overhead to create the required magnetization steady state is required, but the related overhead (‘start-up cycles’) is far less than that needed for duty cycle constraints.

In an advanced, optimised case, the examination order would look like {T2-TSE-segment1; diffusion-segment1; T1-FFE; MRA-chunk1; T2-TSE-segment2; diffusion-segment2; FLAIR; MRA-chunk2; T2-TSE-segment3; diffusion-segment3; MRA-chunk3} etc.

Other mixing approach are feasible, since several sequences are separated into ‘packages’ to prevent slice cross-talk. The packages can easily be used to split up the sequence, even if there is no need from a duty cycle perspective for that particular scan (like the FLAIR), but the enable further segregation of duty-cycle limited sequences.

1. A magnetic resonance imaging system comprising
an RF-excitation module to generate one of several RF-excitations
a gradient module to generate one of several magnetic gradient pulses
a control unit to control the RF-excitation module and the gradient module and the control unit being arranged to
perform an acquisition sequence containing a succession of RF-excitations and gradient pulses
the acquisition sequence comprising several acquisition segments in which magnetic resonance signals are generated, in respective segments the magnetic resonance signals pertaining to different contrast types
individual acquisition segments have one or several repetitive acquisition units, magnetic resonance signals in an individual acquisition unit pertaining to the same contrast type.

2. A magnetic resonance imaging system as claimed in claim 1, wherein the control unit is further arranged to set the duration of the respective acquisition segments and/or the order of contrast types of the acquisition segments on the basis of constraint(s) imposed by the content of the acquisition segments.

3. A magnetic resonance imaging system as claimed in claim 2, wherein the control unit is further arranged to set the duration of the respective acquisition segments and/or the order of contrast types of the acquisition segments on the basis of said constraint(so) within a pre-selected safety margin.

4. A magnetic resonance imaging system as claimed in claim 2, wherein the control unit is arranged to receive user input to set the duration of the respective acquisition segments.

5. A magnetic resonance imaging system as claimed in claim 2, wherein the control unit is arranged to compute the durations of the respective acquisition segments from the content of the acquisition segments.

6. A magnetic resonance imaging system as claimed in claim 1,
comprising a receiver module to acquire the magnetic resonance signals and a reconstruction module to reconstruct one or several magnetic resonance images from the magnetic resonance signals, wherein
the control unit is also arranged to control the receiver module to collect magnetic resonance signals from respective acquisition segments to form respective collections of magnetic resonance signals and
the control unit is also arranged to control the reconstruction module to reconstruct the respective magnetic resonance images from the individual collections of magnetic resonance signals.

7. A magnetic resonance imaging method including steps
to perform an acquisition sequence containing a succession of RF-excitations and gradient pulses
the acquisition sequence comprising several acquisition segments in which magnetic resonance signals are generated, in respective segments the magnetic resonance signals pertaining to different contrast types
individual acquisition segments have one or several repetitive acquisition units, magnetic resonance signals in an individual acquisition unit pertaining to the same contrast type.

8. A computer programme including instructions to
to perform an acquisition sequence containing a succession of RF-excitations and gradient pulses
the acquisition sequence comprising several acquisition segments in which magnetic resonance signals are generated, in respective segments the magnetic resonance signals pertaining to different contrast types
individual acquisition segments have one or several repetitive acquisition units, magnetic resonance signals in an individual acquisition unit pertaining to the same contrast type.
